(19) United States
(12) Patent Application Publication
(10) Pub. No.: US 2021/0262092 A1
(43) Pub. Date: Aug. 26, 2021

(54) SEQUENTIAL PULSE AND PURGE FOR ALD PROCESSES

(71) Applicant: Applied Materials, Inc., Santa Clara, CA (US)

(72) Inventors: Muhammad M. Rasheed, San Jose, CA (US); Mandyam Sriram, San Jose, CA (US); Anqing Cui, Palo Alto, CA (US); Sanjeev Baluja, Campbell, CA (US); Kevin Griffin, Livermore, CA (US); Joseph AuBuchon, San Jose, CA (US)

(73) Assignee: Applied Materials, Inc., Santa Clara, CA (US)

(21) Appl. No.: 17/186,594

(22) Filed: Feb. 26, 2021

Related U.S. Application Data
(60) Provisional application No. 62/981,865, filed on Feb. 26, 2020.

(51) Int. Cl. C23C 16/455; C23C 16/44

(52) U.S. Cl. CPC C23C 16/45557; C23C 16/45512; C23C 16/4408; C23C 16/45519; C23C 16/45525

(57) ABSTRACT

Gas delivery systems and methods of delivering a process gas are described. The gas delivery system includes an inert gas line and a first reactive gas line connected to a gas line with a purge gas flow. The flows of inert gas and first reactive gas are controlled so that the pressure at the end of the gas line remains substantially constant.

### CROSS-REFERENCE TO RELATED APPLICATIONS

This application claims priority to U.S. Provisional Application No. 62/981,865, filed Feb. 26, 2021, the entire disclosure of which is hereby incorporated by reference herein.

### TECHNICAL FIELD

Embodiments of the present disclosure pertain to the field of electronic device manufacturing. More particularly, embodiments of the disclosure relate to apparatus and methods for sequential pulse and purge to enable fast cycle times.

### BACKGROUND

Several deposition techniques are used during semiconductor manufacturing including atomic layer deposition (ALD) and chemical vapor deposition (CVD). In both of these processes, a precursor or reactive gas is commonly co-flowed with a carrier or inert gas. In many processes, the co-flowed precursor/carrier gas is pulsed into an inert gas flow to create a pulsed process sequence.

For ALD or other cyclic processes, film quality is achieved by separating reactable chemistries in the gas phase. Thus, purge out with inert gas is required between the reactive chemical doses. Typical ALD process involves repeated cycles of Precursor 1->Inert Purge->Precursor 2->Inert Purge to obtain a film with a predetermined thickness. A carrier gas is typically used with liquid or solid precursor to increase precursor flux. This precursor gas delivery is pulsed using fast cycle valves or ALD valves. However for all instances the purge gas flows continuously.

During the pulse steps, total flow increases due to co-flowing high amounts of gaseous precursors along with high purge flows resulting in higher pressures. The subsequent purge steps, where gaseous precursor flow is turned off and only the purge gas is flowed, results in a decrease in the total flow and pressure drop. The changes in pressure and flow rate result in non-optimum process results due to the inability to operate a lower pressures and very fast pressure cycling.

Accordingly, there is a need in the art for apparatus and methods to minimize cycle time and/or maximize throughput by controlling pressure and/or gas flow differentials.

### SUMMARY

One or more embodiments of the disclosure are directed to gas delivery systems comprising a gas line having a first end and a second end defining a length. The first end is configured to be connected to a purge gas source and the second end is configured to be connected with a process chamber. An inert gas line is in fluid communication with the gas line. The inert gas line is connected to the gas line along the length of the gas line between the first end and the second end. A first reactive gas line is in fluid communication with the gas line. The first reactive gas line is connected to the gas line along the length of the gas line between the inert gas line and the second end.

Additional embodiments of the disclosure are directed to methods of providing a gas flow. A constant flow of purge gas is provided into a first end of a gas line having a first end and a second end in fluid communication. The first end and second end of the gas line define a length of the gas line. Alternately pulsing a flow of inert gas into an inert gas line and a flow of a first reactive gas into a first reactive gas line. The inert gas line and first reactive gas line are in fluid communication with the gas line along the length of the gas line with the first reactive gas line downstream of the inert gas line. The flow of inert gas and flow of reactive gas pulses are configured to provide a uniform pressure at the second end of the gas line.

Further embodiments of the disclosure are directed to non-transitory computer readable medium including instructions, that, when executed by a controller of a gas delivery system, causes the gas delivery system to perform operations of: providing a constant flow of a purge gas into a first end of a gas line, the gas line having a first end and a second end defining a length; providing a pulse of an inert gas through an inert gas line in fluid communication with the gas line between the first end and the second end; providing a pulse of a first reactive gas through a first reactive gas line in fluid communication with the gas line downstream of the inert gas line; and coordinating the pulses of inert gas and first reactive gas to provide a total flow rate and pressure at the second end of the gas line so that the pressure remains substantially uniform.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a schematic representation of a gas delivery system according to one or more embodiment of the disclosure;

FIG. 2 illustrates a schematic representation of a gas delivery system according to one or more embodiment of the disclosure;

FIG. 3 illustrates a pulse sequence for a method according to one or more embodiment of the disclosure; and

FIG. 4 illustrates a pulse sequence for a method according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

Instead of co-flowing inert purge gas along with cyclical gaseous precursor pulsing, some embodiments of the disclosure provide apparatus and methods that enable both inert and precursor flow in cyclical mode that are out of sync. In some embodiments, a sequential pulse and purge process cycles inert purge gas out of phase with the precursor cycle. One or more embodiments of the disclosure have very high inert pulse which is more efficient in reducing cycle time. In some embodiments, a dose of precursor is increased to obtain better ALD film properties, like step coverage. Some embodiments advantageously reduce pressure fluctuations in the process chamber.

In one or more embodiments, the arrangement and use of ALD valves enable fast cycle times. In some embodiments, fast cycle times are achieved by adding an additional fast valve upstream of the chemical dosing valve. In some embodiments, the upstream purge valve is connected to a pressure reservoir filled with inert or alternate gas. After opening and closing dose valve (dose step), purge valve is opened allowing fast response time of high flow inert gas to purge the chemistry out of the line and downstream volume.

Some embodiments provide an arrangement of valves (including additional fast valves upstream of dose valve). In some embodiments, adding an inert pressure reservoir enables very fast response time of the high flow inert gas. Some embodiments provide a valve manifold block with minimum trapped volume. Some embodiments provide a valve manifold block with minimum volume between two valves. Some embodiments provide a valve manifold block with high conductance purge feedthrough. Some embodiments provide apparatus and methods for delivering chemistry changes with response rates less than 50 msec. Some embodiments provide apparatus and methods with faster response rates than with mass flow controllers (MFC). Some embodiments provide apparatus and methods for delivering chemistry without a high flow constant purge that dilutes the chemistry and requires high process pressures.

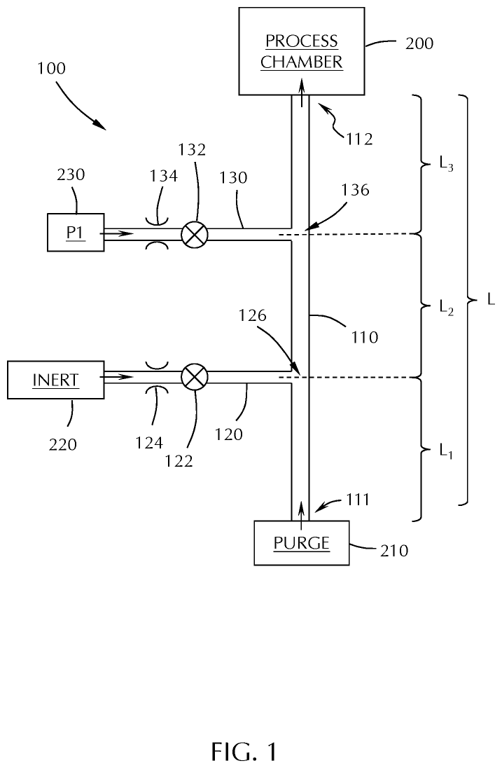

FIG. 1 illustrates a gas delivery system 100 according to one or more embodiment of the disclosure. A gas line 110 has a first end 111 and a second end 112 defining a length L of the gas line 110. The first end 111 is configured to be connected to a purge gas source 210. The second end 112 is configured to be connected to a process chamber 200. In some embodiments, the first end 111 is connected to the purge gas source 210. In some embodiments, the second end 112 is connected to the process chamber 200.

An inert gas line 120 is in fluid communication with the gas line 110. As used in this specification and the appended claims, the term “fluid communication” means that a fluid (e.g., a precursor containing gas) can flow from one designated component to another designated component within the enclosed system without significant leakage. The inert gas line 120 is configured to be connected to an inert gas source 220. In some embodiments, the inert gas line 120 is connected to and in fluid communication with an inert gas source 220.

The inert gas line 120 of some embodiments is connected to the gas line 110 along the length L of the gas line 110 between the first end 111 and the second end 112. In some embodiments, the inert gas line 120 is connected to the gas line 110 at a distance L₁ from the first end 111. The distance L₁ is measured from the mid-point of the width of the inert gas line 120, as illustrated in FIG. 1. In some embodiments, distance L₁ is in the range of 5% to 95% of the length L, or in the range of 10% to 90% of the length L, or in the range of 20% to 80% of the length L, or in the range of 30% to 70% of the length L, or in the range of 40% to 60% of the length L. In some embodiments, the distance L₁ is less than 100 cm, 75 cm, 50 cm, 25 cm, 20 cm, 15 cm or 10 cm from the first end 111.

In some embodiments, a first reactive gas line 130 is in fluid communication with the gas line 110. It will be understood that the term “first” is merely used as a means of identifying a reactive gas line and does not imply any particular order or arrangement of components. The first reactive gas line 130 of some embodiments is configured to be connected to a first reactive gas source 230, also referred to as a first precursor or P1. In some embodiments, the first reactive gas line 130 is connected to and in fluid communication with a first reactive gas source 230.

The first reactive gas line 130 of some embodiments is connected to the gas line 110 along the length L of the gas line 110 between the first end 111 and the second end 112. In some embodiments, the first reactive gas line 130 is connected to the gas line 110 at a distance L₂ from the first end 111 of the gas line 110. The distance L₂ is measured from the mid-point of the width of the first reactive gas line 130, as illustrated in FIG. 1. In some embodiments, the first reactive gas line 130 is connected to the gas line 110 along a length of the gas line 110 between the inert gas line 120 and the second end 112. In some embodiments, the first reactive gas line 130 is connected to the gas line 110 at a distance L₂ from the inert gas line 120. In some embodiments, the distance L₂ is in the range of 5% to 95% of the length L, or in the range of 10% to 90% of the length L, or in the range of 20% to 80% of the length L, or in the range of 30% to 70% of the length L, or in the range of 40% to 60% of the length L. In some embodiments, the distance L₂ is less than 100 cm, 75 cm, 50 cm, 25 cm, 20 cm, 15 cm or 10 cm from the inert gas line 120. In some embodiments, the first reactive gas line 130 is connected to the gas line 110 at a distance L₃ from the second end 112. In some embodiments, distance L₃ is in the range of 5% to 95% of the length L, or in the range of 10% to 90% of the length L, or in the range of 20% to 80% of the length L, or in the range of 30% to 70% of the length L, or in the range of 40% to 60% of the length L. In some embodiments, the distance L₃ is less than 100 cm, 75 cm, 50 cm, 25 cm, 20 cm, 15 cm or 10 cm from the second end 112.

In some embodiments, the first reactive gas line 130 is connected to the gas line 110 at a position (distance L₃) sufficient to provide a flow of first reactive gas to the second end 112 of the gas line 110 within 100 msec of opening the first reactive gas valve for a predetermined flow rate.

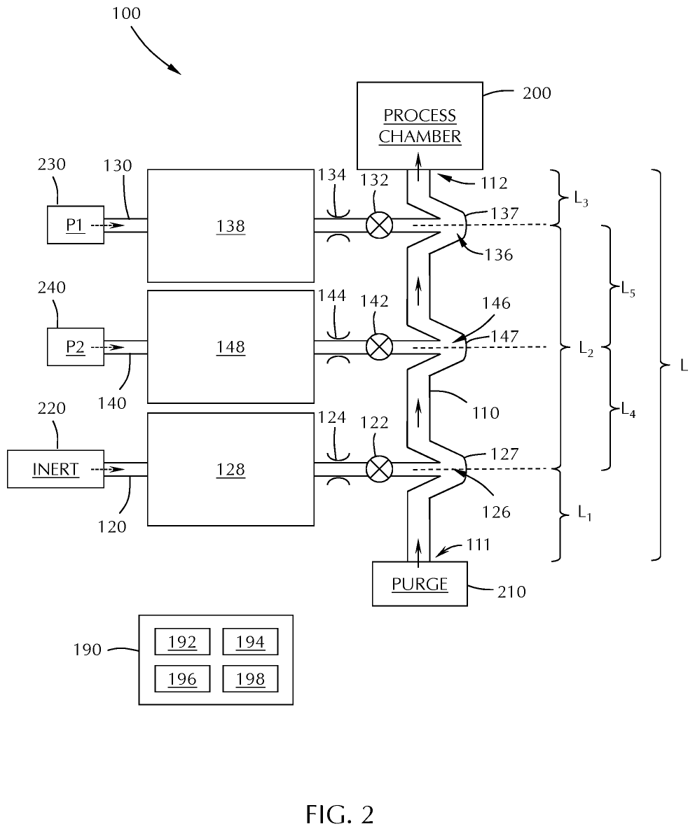

Referring to FIG. 2, one or more embodiments comprise a second reactive gas line 140 in fluid communication with the gas line 110. In some embodiments, the second reactive gas line 140 is configured to be connected to a second reactive gas source 240, also referred to as a second precursor or P2. In some embodiments, the second reactive gas line 140 is connected to and in fluid communication with a second reactive gas 240.

In some embodiments, the second reactive gas line 140 is connected to the gas line 110 along the length L of the gas line 110 between the inert gas line 120 and the second end 112. In some embodiments, the second reactive gas line 140 is connected to the gas line 110 downstream of the inert gas line 120 and upstream of the first reactive gas line 130, as shown in FIG. 2. In some embodiments, the second reactive gas line 140 is downstream of both the inert gas line 120 and the first reactive gas line 130. The order of the first reactive gas line 130 and the second reactive gas line 140 depends on, for example, the reactivity, identity, flow rates, pressure and pulse time. For example, the first reactive gas in some embodiments is a metal precursor and the second reactive gas is nitrogen, which will be ignited into a plasma within the process chamber. In this example, the metal precursor is closer to the process chamber, and the nitrogen is able to flush the lines of the metal precursor during normal processing.

The second reactive gas line 140 of some embodiments is connected to the gas line 110 along the length L of the gas line 110 between the first end 111 and the second end 112. In some embodiments, the second reactive gas line 140 connects to the gas line 110 at a distance from the first end 111 of the gas line 110, defined as the sum of L₁ and L₄, where L₄ is the distance from the inert gas line 120 to the second reactive gas line 140. The distance L₄ is measured from the mid-point of the width of the second reactive gas line 140, as illustrated in FIG. 2. In some embodiments, the second reactive gas line 140 connects to the gas line 110 at a distance L₄ from the inert gas line 120. In some embodiments, the second reactive gas line 140 is connected to the gas line 110 along the length L of the gas line 110 between the first reactive gas line 130 and the second end 112. In some embodiments, the second reactive gas line 140 is connected to the gas line 110 along the length L of the gas line 110 between the inert gas line 120 and the first reactive gas line 130. In some embodiments, the second reactive gas line 140 is connected to the gas line 110 at a distance L₄ from the inert gas line 120. In some embodiments, the distance L₄ is in the range of 5% to 60% of the length L, or in the range of 10% to 55% of the length L, or in the range of 20% to 50% of the length L, or in the range of 25% to 45% of the length L, or in the range of 30% to 40% of the length L. In some embodiments, the distance L₄ is less than 100 cm, 75 cm, 50 cm, 25 cm, 20 cm, 15 cm or 10 cm from the inert gas line 120. In some embodiments, the second reactive gas line 140 is connected to the gas line 110 at a distance from the second end 112. In some embodiments, distance between the second reactive gas line 140 to the second end 112 is in the range of 5% to 75% of the length L, or in the range of 10% to 70% of the length L, or in the range of 15% to 65% of the length L, or in the range of 20% to 60% of the length L, or in the range of 25% to 55% of the length L. In some embodiments, the distance between the second reactive gas line 140 and the second end 112 is less than 100 cm, 75 cm, 50 cm, 25 cm, 20 cm, 15 cm or 10 cm.

In some embodiments, the second reactive gas line 140 is connected to the gas line at a distance L₅ upstream of the first reactive gas line 130. In some embodiments, the second reactive gas line 140 is connected to the gas line 110 at a distance downstream of the first reactive gas line 130. In some embodiments, distance between the second reactive gas line 140 and the first reactive gas line is in the range of 5% to 75% of the length L, or in the range of 10% to 70% of the length L, or in the range of 15% to 65% of the length L, or in the range of 20% to 60% of the length L, or in the range of 25% to 55% of the length L. In some embodiments, the distance between the second reactive gas line 140 and the second end 112 is less than 100 cm, 75 cm, 50 cm, 25 cm, 20 cm, 15 cm or 10 cm.

Referring to both FIGS. 1 and 2, in some embodiments the inert gas line 120 comprises an inert gas valve 122. The inert gas valve 122 can be positioned at any suitable distance from the junction 126 with the gas line 110. In some embodiments, the inert gas valve 122 is positioned a distance from the gas line 110 less than 100 cm, 75 cm, 50 cm, 25 cm, 20 cm, 15 cm or 10 cm from the junction 126.

In some embodiments, the first reactive gas line 130 comprises a first reactive gas valve 132. The first reactive gas valve 132 can be positioned at any suitable distance from the junction 136 with the gas line 110. In some embodiments, the first reactive gas valve 132 is positioned a distance from the gas line 110 less than 100 cm, 75 cm, 50 cm, 25 cm, 20 cm, 15 cm or 10 cm from the junction 136.

In some embodiments, the second reactive gas line 140 comprises a second reactive gas valve 142. The second reactive gas valve 142 can be positioned at any suitable distance from the junction 148 with the gas line 110. In some embodiments, the second reactive gas valve 142 is positioned a distance from the gas line 110 less than 100 cm, 75 cm, 50 cm, 25 cm, 20 cm, 15 cm or 10 cm from the junction 146.

In some embodiments, one or more of the inert gas valve 122, the first reactive gas valve 132 or the second reactive gas valve 142 comprises a fast switching valve. A fast switching valve (also referred to as a fast pulsing valve or high speed valve) of some embodiments is configured to open and/or close within 50 milliseconds. The open/close time is measured based on the physical movement of the valve components, and is independent of any delay due to the electrical signal transmission to the valve. In some embodiments, each of the inert gas valve 122 and the first reactive gas valve 132 are fast switching valves. In some embodiments, each of the inert gas valve 122 and the first reactive gas valve 132 are fast switching valves and the second reactive gas valve 142, if one is present, is not a fast switching valve. In some embodiments, each of the inert gas valve 122, the first reactive gas valve 132 and the second reactive gas valve 142 are fast switching valves. In some embodiments, each of the inert gas valve 122 and the second reactive gas valve 142 are fast switching valves. In some embodiments, each of the inert gas valve 122 and the second reactive gas valve 142 are fast switching valves, and the first reactive gas valve 132 is not a fast switching valve. In some embodiments, each of first reactive gas valve 132 and the second reactive gas valve 142 are fast switching valves. In some embodiments, each of first reactive gas valve 132 and the second reactive gas valve 142 are fast switching valves, and the inert gas valve 122 is not a fast switching valve. In some embodiments, the fast switching valve is configured to open and/or close within 40 milliseconds, 30 milliseconds, 20 milliseconds or 10 milliseconds. In some embodiments, the fast switching valve opens and closes within 50, 40, 30, 20 or 10 milliseconds. In some embodiments, the fast switching valve is a valve that is either fully open or fully closed. In some embodiments, the fast switching valve is a variable open valve that allows modulation of the flow profile through the valve.

In some embodiments, the inert gas line 120 further comprises an orifice 124 positioned upstream of the inert gas valve 122. As used herein, the terms “upstream” and “downstream” refer to relative directions or positions according to the flow of a fluid toward the second end 112 of the gas line 110. In some embodiments, the first reactive gas line 130 further comprises a first reactive gas orifice 134 upstream of the first reactive gas valve 132. In some embodiments, the second reactive gas line 140 further comprises a second reactive gas orifice 144 upstream of the second reactive gas valve 142. The orifice 124, 134, 144 can be any suitable orifice that restricts flow through the respective gas line. The orifice size depends on, for example, the particular predetermined gas flow through the orifice, the operating pressure and/or the flow rate of gas through the orifice. The orifice of some embodiments is a disk-shaped component with a precise aperture extending there through. In some embodiments, the orifice has a size in the range of about 100 μm to about 1500 μm. In some embodiments, the orifice has an opening in the range of about 200 μm to about 1000 μm.

One or more embodiments of the disclosure, as shown in FIG. 2, further comprise an inert gas reservoir 128 positioned upstream of the inert gas orifice 124. Some embodiments further comprise a first reactive gas reservoir 138 positioned upstream of the first reactive gas orifice 134. Some embodiments further comprise a second reactive gas reservoir 148 positioned upstream of the second reactive gas orifice 144. The reservoir of some embodiments has a volume and/or pressure sufficient to provide a pulse of gas with uniform flow/pressure. In some embodiments, the reservoir is pressurizable greater than 10×, 50×, 100×, 500×, 1000× required to provide a uniform flow through the orifice upon opening of the valve.

As shown in FIG. 2, some embodiments of the disclosure include one or more mixing chamber along the length L of the gas line 110. Some embodiments include an inert gas mixing chamber 127 at the junction 126 of the as line 110 and the inert gas line 120. Some embodiments include a first reactive gas mixing chamber 137 at the junction 136 of the gas line 110 and the first reactive gas line 130. Some embodiments include a second reactive gas mixing chamber 147 at the junction 146 of the gas line 110 and the second reactive gas line 140. In some embodiments, the mixing chamber provides a volume along the flow path of the gas line 110 that allows the gas in the gas line 110 to mix with the gas coming in from the junction. The mixing chamber of some embodiments allows for mixing without backflow toward the inert or reactive gas lines.

Referring to FIG. 2, some embodiments further comprise at least one controller 190. In some embodiments, the at least one controller 190 has a processor 192 (also referred to as a CPU), a memory 194 coupled to the processor 192, input/output devices 196 coupled to the processor 192, and support circuits 198 to communication between the different electronic components. In some embodiments, the memory 194 includes one or more of transitory memory (e.g., random access memory) or non-transitory memory (e.g., storage).

The memory 194, or computer-readable medium, of the processor may be one or more of readily available memory such as random access memory (RAM), read-only memory (ROM), floppy disk, hard disk, or any other form of digital storage, local or remote. The memory 194 can retain an instruction set that is operable by the processor 192 to control parameters and components of the system. The support circuits 198 are coupled to the processor 192 for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 190 has one or more configurations to execute individual processes or sub-processes to perform the method. In some embodiments, the controller 190 is connected to and configured to operate intermediate components to perform the functions of the methods. For example, the controller 190 of some embodiments is connected to and configured to control one or more of gas valves, actuators, motors, slit valves, vacuum control, etc.

The controller 190 of some embodiments has one or more configurations selected from: a configuration to control a flow of a purge gas from the first end through the length of the gas line; a configuration to control a flow of an inert gas through the inert gas line; a configuration to control a flow of a first reactive gas through the first reactive gas line; a configuration to open and/or close the first reactive gas valve; a configuration to open and/or close the inert gas valve; or a configuration to pulse the flow an inert gas through the gas line and a flow of a first reactive gas through the first reactive gas line so that a pressure at the second end of the gas line remains substantially uniform. In some embodiments, the controller 190 has one or more of: a configuration to control a flow of a purge gas from the first end through the length of the gas line; a configuration to control a flow of an inert gas through the inert gas line; a configuration to control a flow of a first reactive gas through the first reactive gas line; a configuration to control a flow of a second reactive gas through the second reactive gas line; a configuration to open and/or close the first reactive gas valve; a configuration to open and/or close the inert gas valve; a configuration to open and/or close the second reactive gas valve; or a configuration to pulse the flow an inert gas through the gas line, a flow of a first reactive gas through the first reactive gas line and a flow of a second reactive gas through the second reactive gas line so that a pressure at the second end of the gas line remains substantially uniform.

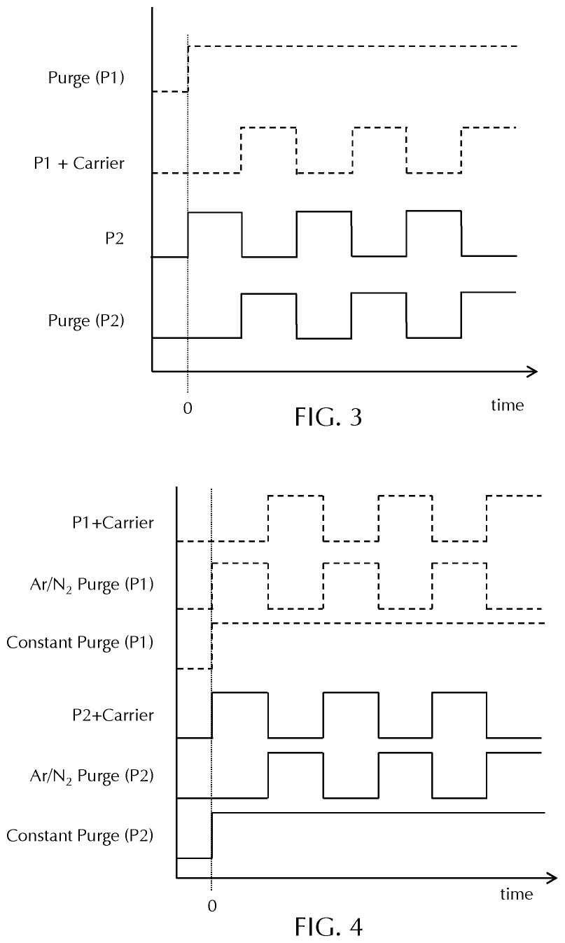

One or more embodiments of the disclosure are directed to methods of providing a gas flow. A constant flow of purge gas is provided into a first end 111 of a gas line 110. Pulses of a flow of an inert gas into an inert gas line 120 and a flow of a first reactive gas in first reactive gas line 130 are alternately provided into the gas line 110. The first reactive gas line 130 of some embodiments is downstream of the inert gas line 120, relative to the first end 111 of the gas line 110. The flow of inert gas and the flow of reactive gas are pulsed in a profile configured to provide a uniform pressure at the second end of the gas line. FIG. 3 illustrates a method in accordance with one or more embodiment of the disclosure. At time zero, the purge gas in gas line 110 is flowed at a constant pressure. The illustration shows the purge gas flow starting at time zero. In some embodiments, the purge gas flow begins prior to initiation of the method.

In some embodiments, as shown in FIG. 4, the method further comprises pulsing a flow of a second reactive gas into a second reactive gas line in fluid communication with the gas line along the length of the gas line downstream of the inert gas line, and wherein the flow of inert gas and flow of first reactive gas pulses an second reactive gas pulses are configured to provide a uniform pressure at the second end of the gas line.

Additional embodiments of the disclosure are directed to non-transitory computer readable medium including instructions, that, when executed by a controller of a gas delivery system, causes the gas delivery system to perform operations of: providing a constant flow of a purge gas into a first end of a gas line, the gas line having a first end and a second end defining a length; providing a pulse of an inert gas through an inert gas line in fluid communication with the gas line between the first end and the second end; providing a pulse of a first reactive gas through a first reactive gas line in fluid communication with the gas line downstream of the inert gas line; and coordinating the pulses of inert gas and first reactive gas to provide a total flow rate and pressure at the second end of the gas line so that the pressure remains substantially uniform. In some embodiments, the non-transitory computer readable medium further comprises instructions, that, when executed by the controller of the gas delivery system, causes the gas delivery system to perform operations of: providing a pulse of a second reactive gas through a second reactive gas line in fluid communication with the gas line downstream of the inert gas line; and coordinating the pulses of inert gas, first reactive gas and second reactive so that the pressure at the second end of the gas line remains substantially uniform. In some embodiments, the non-transitory computer readable medium comprises instructions for operating a method.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A gas delivery system comprising:
a gas line having a first end and a second end defining a length, the first end configured to be connected to a purge gas source, the second end configured to connect with a process chamber;
an inert gas line in fluid communication with the gas line, the inert gas line connected to the gas line along the length of the gas line between the first end and the second end; and
a first reactive gas line in fluid communication with the gas line, the first reactive gas line connected to the gas line along the length of the gas line between the inert gas line and the second end.

2. The gas delivery system of claim 1, wherein the inert gas line comprises an inert gas valve and the first reactive gas line comprises a first reactive gas valve, each of the inert gas valve and the first reactive gas valve are fast switching valves.

3. The gas delivery system of claim 2, wherein the inert gas line further comprises an inert gas orifice positioned upstream of the inert gas valve.

4. The gas delivery system of claim 3, further comprising an inert gas reservoir positioned upstream of the inert gas orifice.

5. The gas delivery system of claim 2, further comprising an inert gas mixing chamber at a junction of the gas line and the inert gas line.

6. The gas delivery system of claim 2, wherein the first reactive gas line further comprises a first reactive gas orifice positioned upstream of the first reactive gas valve.

7. The gas delivery system of claim 6, wherein the first reactive gas line further comprises a first reactive gas reservoir upstream of the first reactive gas orifice.

8. The gas delivery system of claim 2, further comprising a first reactive gas mixing chamber at a junction of the first reactive gas line and the gas line.

9. The gas delivery system of claim 2, further comprising a second reactive gas line in fluid communication with the gas line, the second reactive gas line connected to the gas line along the length of the gas line between the inert gas line and the second end.

10. The gas delivery system of claim 9, wherein the second reactive gas line is connected to the gas line downstream of the first reactive gas line.

11. The gas delivery system of claim 9, wherein the second reactive gas line further comprises a second reactive gas valve comprising a fast switching valve.

12. The gas delivery system of claim 11, wherein the second reactive gas line further comprises a second reactive gas orifice upstream of the second reactive gas valve.

13. The gas delivery system of claim 12, wherein the second reactive gas line further comprises a second reactive gas reservoir upstream of the second reactive gas orifice.

14. The gas delivery system of claim 2, wherein the first reactive gas line is connected to the gas line at a position sufficient to provide a flow of first reactive gas to the second end of the gas line within 100 msec of opening the first reactive gas valve for a predetermined flow rate.

15. The gas delivery system of claim 2, further comprising a controller having one or more of: a configuration to control a flow of a purge gas from the first end through the length of the gas line; a configuration to control a flow of an inert gas through the inert gas line; a configuration to control a flow of a first reactive gas through the first reactive gas line; a configuration to open and/or close the first reactive gas valve; a configuration to open and/or close the inert gas valve; or a configuration to pulse the flow an inert gas through the gas line and a flow of a first reactive gas through the first reactive gas line so that a pressure at the second end of the gas line remains substantially uniform.

16. The gas delivery system of claim 11, further comprising a controller having one or more of: a configuration to control a flow of a purge gas from the first end through the length of the gas line; a configuration to control a flow of an inert gas through the inert gas line; a configuration to control a flow of a first reactive gas through the first reactive gas line; a configuration to control a flow of a second reactive gas through the second reactive gas line; a configuration to open and/or close the first reactive gas valve; a configuration to open and/or close the inert gas valve; a configuration to open and/or close the second reactive gas valve; or a configuration to pulse the flow an inert gas through the gas line, a flow of a first reactive gas through the first reactive gas line and a flow of a second reactive gas through the second reactive gas line so that a pressure at the second end of the gas line remains substantially uniform.

17. A method of providing a gas flow, the method comprising:
providing a constant flow of purge gas into a first end of a gas line, the gas line having a first end and a second end in fluid communication, the first end and second end defining a length of the gas line; and
alternately pulsing a flow of inert gas into an inert gas line and a flow of a first reactive gas into a first reactive gas line, the inert gas line and first reactive gas line in fluid communication with the gas line along the length of the gas line, the first reactive gas line downstream of the inert gas line,
wherein the flow of inert gas and flow of reactive gas pulses are configured to provide a uniform pressure at the second end of the gas line.

18. The method of claim 17, further comprising pulsing a flow of a second reactive gas into a second reactive gas line in fluid communication with the gas line along the length of the gas line downstream of the inert gas line, and wherein the flow of inert gas and flow of first reactive gas pulses an second reactive gas pulses are configured to provide a uniform pressure at the second end of the gas line.

19. A non-transitory computer readable medium including instructions, that, when executed by a controller of a gas delivery system, causes the gas delivery system to perform operations of:
providing a constant flow of a purge gas into a first end of a gas line, the gas line having a first end and a second end defining a length;
providing a pulse of an inert gas through an inert gas line in fluid communication with the gas line between the first end and the second end;
providing a pulse of a first reactive gas through a first reactive gas line in fluid communication with the gas line downstream of the inert gas line; and
coordinating the pulses of inert gas and first reactive gas to provide a total flow rate and pressure at the second end of the gas line so that the pressure remains substantially uniform.

20. The non-transitory computer readable medium of claim 19, further comprising instructions, that, when executed by the controller of the gas delivery system, causes the gas delivery system to perform operations of:
providing a pulse of a second reactive gas through a second reactive gas line in fluid communication with the gas line downstream of the inert gas line; and
coordinating the pulses of inert gas, first reactive gas and second reactive so that the pressure at the second end of the gas line remains substantially uniform.
